(19) United States
(12) Patent Application Publication
(10) Pub. No.: US 2026/0235898 A1
(43) Pub. Date: Aug. 13, 2026

(54) ENCAPSULATION OF THIN FILM LITHIUM-CONTAINING FILMS FOR 3 DIMENSIONAL INTEGRATION

(71) Applicant: HyperLight Corporation, Cambridge, MA (US)

(72) Inventors: Fan Ye, Lincoln, MA (US); Mian Zhang, Cambridge, MA (US)

(21) Appl. No.: 19/408,075

(22) Filed: Dec. 3, 2025

Related U.S. Application Data
(63) Continuation-in-part of application No. 19/187,834, filed on Apr. 23, 2025.
Application No. 19/187,834 is a continuation of application No. 18/208,818, filed on Jun. 12, 2023, now Pat. No. 12,306,481.
(60) Provisional application No. 63/351,723, filed on Jun. 13, 2022.
(60) Provisional application No. 63/728,094, filed on Dec. 4, 2024.

(51) Int. Cl. G02F 1/035; G02F 1/00; G02F 1/03; G02F 1/055; H01S 5/0225

(52) U.S. Cl. CPC G02F 1/035; G02F 1/0018; G02F 1/0311; G02F 1/0316; G02F 1/0551; G02F 1/0556; H01S 5/0225; G02F 2202/20

(57) ABSTRACT

A photonics device is described. The photonics device includes a thin film lithium-containing (TFLC) electro-optic layer, a lithium barrier structure, and an insulating layer between the TFLC electro-optic layer and the lithium barrier structure. The photonics device may also include an additional lithium barrier structure and/or an additional insulating layer. The TFLC electro-optic layer is between the additional lithium barrier structure and the lithium barrier structure.

### CROSS REFERENCE TO OTHER APPLICATIONS

This application claims priority to U.S. Provisional Patent Application No. 63/728,094 entitled ENCAPSULATION OF THIN FILM LITHIUM-CONTAINING FILMS FOR 3 DIMENSIONAL INTEGRATION filed Dec. 4, 2024, which is incorporated herein by reference for all purposes.

This application is a continuation in part of U.S. patent application Ser. No. 19/187,834 entitled DIFFUSION BARRIER LAYER IN LITHIUM NIOBATE-CONTAINING PHOTONIC DEVICES filed Apr. 23, 2025, which is a continuation of U.S. patent application Ser. No. 18/208,818, now U.S. Pat. No. 12,306,481, entitled DIFFUSION BARRIER LAYER IN LITHIUM NIOBATE-CONTAINING PHOTONIC DEVICES filed Jun. 12, 2023, which claims priority to U.S. Provisional Patent Application No. 63/351,723 entitled DIFFUSION BARRIER LAYER IN LITHIUM NIOBATE-CONTAINING PHOTONIC DEVICES filed Jun. 13, 2022, all of which are incorporated herein by reference for all purposes.

### BACKGROUND OF THE INVENTION

Integrated device manufacturers (IDMs) fabricate electro-optic devices. For example, an IDM may perform silicon photonics (SiPh) device design, fabrication, test, and assembly up to and including module assembly. IDMs may also perform heterogeneous integration. For example, III-V laser diode chiplets may be bonded to a SiPh wafer including silicon-on-insulator (SOI) waveguides to provide heterogenous integrated circuits.

Thin film lithium-containing (TFLC) electro-optic materials (TFLC materials) may include thin film lithium niobate (TFLN) and/or thin film lithium tantalate (TFLT). Such TFLC materials may be desired to be used in optical devices. For example, some TFLC materials have a large modulation in the index of refraction for a given applied electric field, which is desirable. However, integration of TFLC materials may face challenges. For example, processing of TFLN and/or TFLT may be difficult to scale or result in larger than desired optical and/or microwave losses. Further, if integrated with SiPh devices, lithium contamination and lithium diffusion may adversely affect performance. For example, complementary-metal-oxide-semiconductor (CMOS) devices are very sensitive to contamination from materials such as lithium. Thus, the use of TFLC materials may be problematic, particularly for heterogeneous devices such as TFLN-SiPh heterogeneous integrated devices and/or TFLT-SiPh heterogeneous integrated devices. Accordingly, what is desired is a mechanism for incorporating TFLC materials into photonics devices, particularly into heterogeneous integrated circuits.

### BRIEF DESCRIPTION OF THE DRAWINGS

Various embodiments of the invention are disclosed in the following detailed description and the accompanying drawings.

FIGS. 1A-1H are diagrams depicting embodiments of an electro-optic device during fabrication.

FIGS. 2A-2B depict an embodiment of a portion of a thin film lithium-containing optical device usable in an integrated photonics package.

FIGS. 3A-3G are diagrams depicting embodiments of an electro-optic device during fabrication.

FIG. 4 depicts an embodiment of a TFLN on insulator circuit.

FIGS. 5A-5B depict embodiments of heterogeneous integrated devices that include electro-optic layers having Li.

FIGS. 6A-6B depict an embodiment of a photonics device including barrier structures.

FIGS. 7A-7B depict an embodiment of a photonics device including barrier structures.

FIGS. 8A-8C depict an embodiment of a photonics device including barrier structures.

FIG. 9 is a flow chart depicting an embodiment of a method for providing an electro-optic device including a barrier structure.

FIG. 10 is a flow chart depicting an embodiment of a method for providing an electro-optic device including a barrier structure.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

Integration of thin film lithium containing (TFLC) electro-optic materials (TFLC materials) such as thin film lithium niobate (TFLN) and/or thin film lithium tantalate (TFLT) may face challenges. Processing of TFLC photonic integrated circuits (PICs) may be difficult to scale or result in larger than desired optical losses and/or microwave losses. For integration with silicon photonics (SiPh) devices, lithium contamination may be an issue. For example, lithium is considered an alkali contamination, which is known to shift the threshold voltage of CMOS transistors. Thus, Li contamination is particularly an issue for CMOS devices. Contamination of manufacturing equipment is also undesirable. Lithium diffusion may also be problematic. Lithium readily diffuses in Si and SiO₂ among other mediums. For other photonics devices, such as Si or SiN photonics devices, lithium contamination and lithium diffusion may adversely affect performance. Thus, Li diffusion could adversely affect the functioning of the circuit with which the TFLC material(s) is combined or circuits fabrication on other wafers fabricated using the same equipment. Lithium is also known to diffuse within lithium niobate. Thus, the use of TFLC materials in electro-optic devices may be difficult to achieve, particularly for heterogeneous devices such as TFLN-SiPh heterogeneous integrated devices and/or TFLT-SiPh heterogeneous integrated devices.

A photonics device is described. The photonics device includes a thin film lithium-containing (TFLC) electro-optic layer, a lithium barrier structure, and an insulating layer between the TFLC electro-optic layer and the lithium barrier structure. The photonics device may also include an additional lithium barrier structure and/or an additional insulating layer. The TFLC electro-optic layer is between the additional lithium barrier structure and the lithium barrier structure. In some embodiments, the lithium barrier structure includes a lithium barrier layer.

The TFLC electro-optic layer includes at least one waveguide having a waveguide width. The lithium barrier structure may have a width of at least twenty-five multiplied by the waveguide width. In some such embodiments, the lithium barrier structure extends across the photonics device. The lithium barrier structure may include or consist of at least one of a low permeability material or a low diffusivity constant material. For example, the lithium barrier structure may include at least one of a silicon nitride layer, a silicon oxynitride layer, an aluminum oxide layer, a titanium nitride layer, or a tantalum nitride layer.

In some embodiments, the TFLC electro-optic layer includes at least one waveguide. The lithium barrier structure is between the waveguide(s) and additional waveguide(s) of an additional device. The barrier structure is configured to facilitate coupling between the additional waveguide(s) and the waveguide(s) such that a coupling loss between the waveguide(s) and the waveguide(s) of the additional device is not more than 0.1 dB for a constrained coupling length of less than 200 micrometers. In some such embodiments, the waveguide(s) are separated from the additional waveguide(s) by greater than one micrometer. The additional lithium barrier structure is between the waveguide and a substrate.

An integrated photonics device is described. The integrated photonics device includes a TFLC integrated photonics device (TFLC PIC) and an additional integrated circuit. The TFLC PIC includes a waveguide, a first lithium barrier structure, a second lithium barrier structure, a first dielectric layer, a second dielectric layer, and a plurality of electrodes in proximity to a portion of the waveguide. The waveguide includes a TFLC electro-optic material. The waveguide is between the first dielectric layer and the second dielectric layer. The first dielectric layer is between the first lithium barrier structure and the waveguide. The second dielectric layer is between the second lithium barrier structure and the waveguide. The first dielectric layer and the second dielectric layer encapsulate the waveguide. The first lithium barrier structure and the second lithium barrier structure each has a width of at least twenty-five multiplied by a waveguide width. The additional integrated circuit includes an additional waveguide. The second lithium barrier structure is between the additional waveguide and the waveguide. The second barrier structure may be configured to facilitate coupling between the additional waveguide and the waveguide such that a coupling loss between the waveguide and the additional waveguide is not more than 0.1 dB for a constrained coupling length of less than 200 micrometers and a separation between the waveguide and the additional waveguide of greater than one micrometer.

In some embodiment of the integrated photonics device, the first lithium barrier structure and the second lithium barrier structure each extends across the TFLC PIC. At least one of the first lithium barrier structure or the second lithium barrier structure may include a low permeability material and/or a low diffusivity constant material. In some embodiments, the lithium barrier structure includes at least one of a silicon nitride layer, a silicon oxynitride layer, an aluminum oxide layer, a titanium nitride layer, or a tantalum nitride layer.

A method is also described. The method includes providing a first lithium barrier structure, providing a first insulating layer on the first barrier structure, and providing a TFLC electro-optic layer on the first insulating layer, The first insulating layer is between the TFLC electro-optic layer and the first lithium barrier structure. The method also includes providing a second insulating layer on the TFLC electro-optic layer and providing a second lithium barrier structure on the second insulating layer. The second insulating layer is between the TFLC electro-optic layer and the second insulating barrier structure.

The method may also include forming at least one waveguide from the TFLC electro-optic layer, the at least one waveguide having a waveguide width, the first lithium barrier structure and the second lithium barrier structure each having a width of at least twenty-five multiplied by the waveguide width. Each of the first lithium barrier structure and the second lithium barrier structure may include at least one of a silicon nitride layer, a silicon oxynitride layer, an aluminum oxide layer, a titanium nitride layer, or a tantalum nitride layer.

The second lithium barrier structure may be between the waveguide and an additional waveguide of an additional device. In such embodiments, the second lithium barrier structure may be configured to facilitate coupling between the additional waveguide and the waveguide such that a coupling loss between the waveguide and the additional device is not more than 0.1 dB for a constrained coupling length of less than 200 micrometers. In some such embodiments, the waveguide is separated from the additional waveguide by greater than one micrometer.

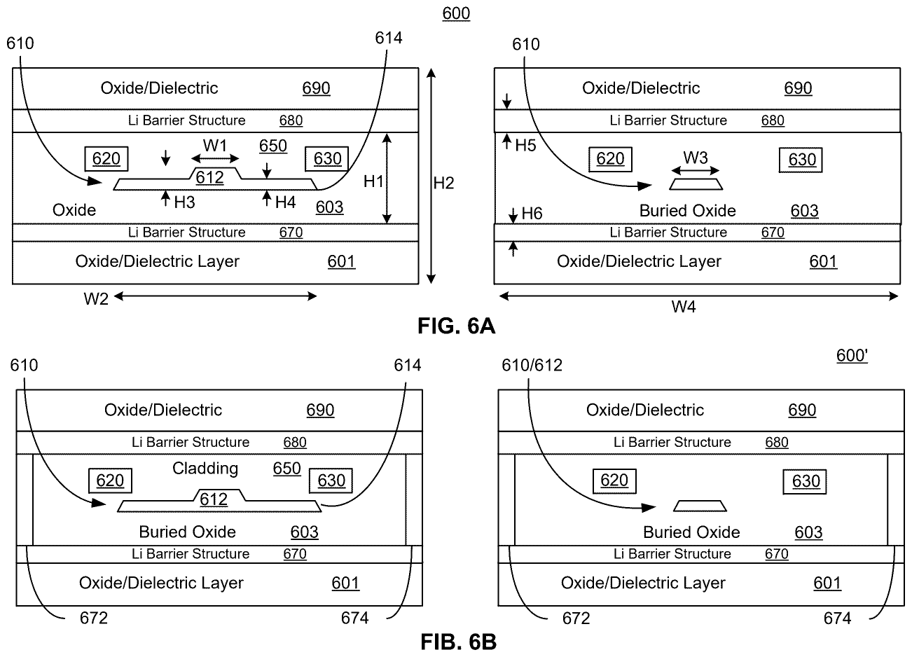

Various features of the electro-optic devices are described herein. One or more of these features may be combined in manners not explicitly described herein. For example, barrier layers may be placed in other locations or have other functions than explicitly shown. For example, barrier layers 672 and 674 of FIG. 6B may be placed closer to waveguide 610.

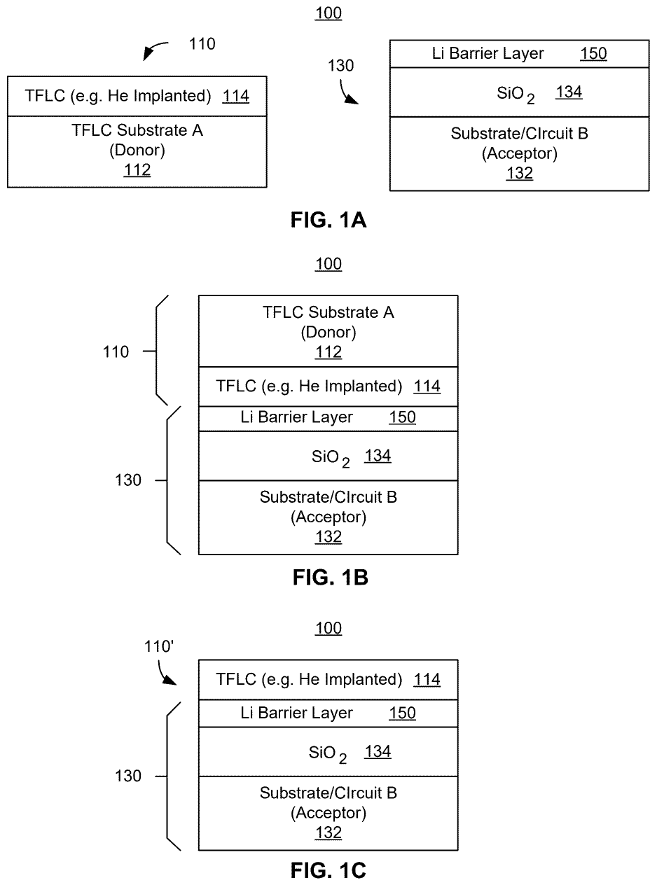

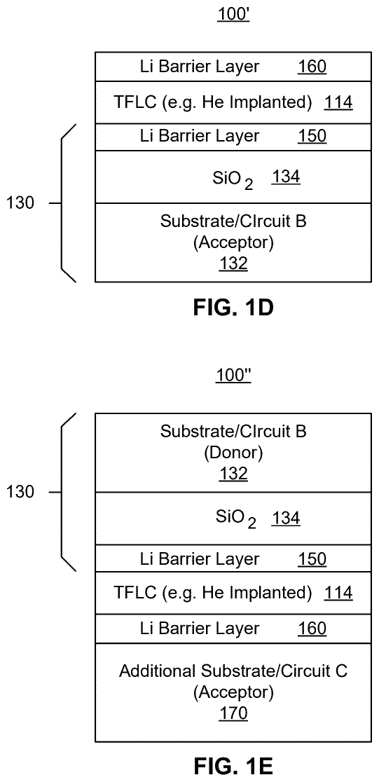

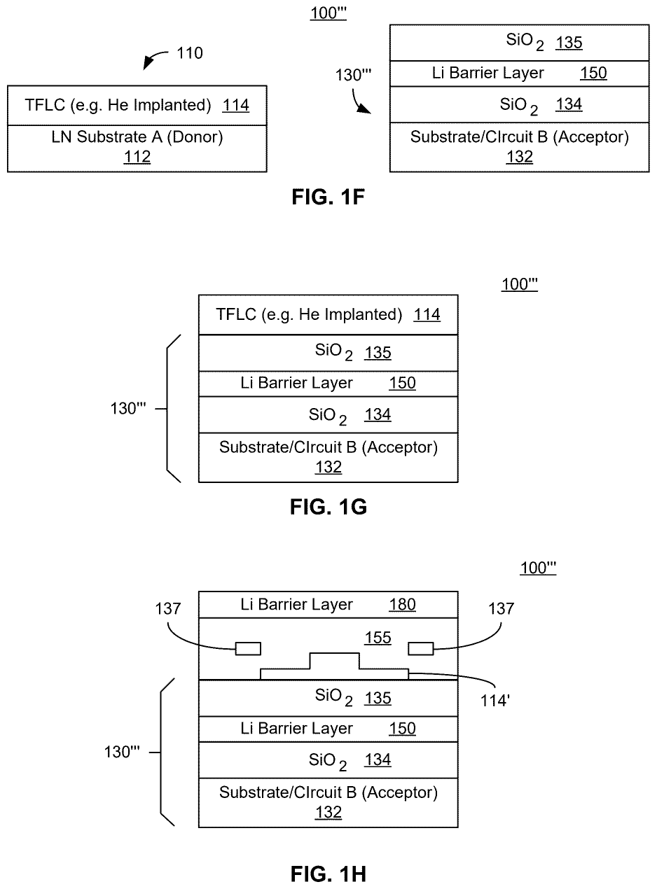

FIGS. 1A-1H are diagrams depicting embodiments of electro-optic devices 100, 100′, 100″, and 100′″ during fabrication. For simplicity, not all components are shown and those portions that are shown are not to scale. In the embodiment shown, a donor circuit A 110 and an acceptor circuit B 120 are utilized. Donor circuit A 110 includes a donor substrate 112 and a thin film lithium-containing electro-optic (TFLC) material 114. Donor substrate A 112, or wafer, has thereon a thin film electro-optic layer 114 that includes Li. In the embodiment shown, TFLC material 114 is a TFLN layer, which may be implanted with He. TFLC layer 114 may include other and/or additional electro-optic layers that include Li in other embodiments. For example, TFLT may be used in lieu of or in addition to TFLN.

Acceptor circuit B 130 includes an acceptor substrate B 132, an oxide layer 134, and a Li barrier structure 150. Acceptor substrate B 132, or wafer, may be a Si wafer having SiO₂ (or other appropriate oxide) layer 132. Because of its position in the final integrated circuit, oxide layer 134 may be considered a buried oxide (BOX) layer. In some embodiments, structures, such as silicon waveguides or other silicon photonics structures and/or CMOS components, may be formed in or on substrate 132. Thus, acceptor substrate B 132 may also be considered to be an acceptor circuit. In other embodiments, acceptor substrate B 132 may be a blank substrate.

Also shown on the acceptor circuit B 130 is Li barrier structure 150. In the embodiment shown, barrier structure 150 is a barrier layer and will be termed a barrier layer for device 100. However, nothing prevents barrier layer 150 from having structures including but not limited to trenches, apertures, a multilayer structure, or other structures. Further, although depicted as flat, barrier layer 150 may have another structure, for example due to underlying topology of acceptor circuit B 130. In some embodiments, Li barrier layer 150 is on TFLC layer 114 of donor circuit A 110. Barrier layer 150 substantially retards and/or prevents the diffusion of lithium through barrier layer 150. Further, barrier layer 150 is sufficiently thin that performance of photonics device 100 being formed is not adversely affected. For example, barrier layer 150 may include one or more of titanium nitride (e.g. at least ten nanometers of TiN that may be formed via atomic layer deposition (ALD)), silicon nitride (e.g. at least 90-100 nanometers or more of SiN that may be formed via PECVD or LPCVD and may be densified by an anneal at anneal temperature(s) of at least 800 degrees Celsius), tantalum nitride (e.g. at least ten nanometers of TiN that may be formed via atomic layer deposition (ALD)), and/or silicon oxynitride (which can have its index of refraction tuned by tuning the nitrogen content). In some embodiments, barrier layer 150 is sufficiently thick to significantly reduce or prevent the formation of pinholes in barrier layer 150. For example, barrier layer 150 may be at least two monolayers (e.g. at least three through ten nanometers) thick. For thicknesses less than those described above (including less than two monolayers), diffusion of Li may be significantly reduced, but not eliminated. However, layer 150 is still termed a barrier layer. In some embodiments, barrier layer 150 is not more than two hundred nanometers thick. In some embodiments, silicon nitride and silicon oxynitride may be used because TaN and TiN are conductive. Consequently, TaN and TiN may be used as or in barrier layers 150 far from structures such as waveguides to reduce eddy currents. In some embodiments, barrier layer 150 is desired to have an index of refraction that differs significantly from the TFLC layer 114 index of refraction. This difference in index of refraction is desired to reduce or prevent the optical mode from being pulled from the TFLC layer 114 into barrier layer 150. Barrier layer 150 of FIG. 1A may function as bonding layer in addition to being a barrier layer. In some embodiments, barrier layer 150 is deposited on the SiO₂ layer. In some embodiments, barrier layer 150 is grown on SiO₂ layer 134 (e.g. via nitridization of the SiO₂ layer).

In FIG. 1B, that donor circuit A 110 has been flipped and bonded with acceptor circuit B 130. Thus, as indicated above, barrier layer 150 also aids in bonding between acceptor and donor circuits 110 and 130. Although shown as the same size in FIG. 1B, nothing prevents the donor circuit A 110 and/or acceptor circuit B 130 from having different sizes. For example, donor circuit A 110 may be a chiplet, while acceptor circuit B 130 may be one of many circuits on an acceptor wafer (e.g. a SiPh wafer) 132. In FIG. 1C, donor substrate 112 has been removed. In some embodiments, the donor substrate 112 may not be completely removed. Thus, in some embodiments, an integrated TFLC photonics device 100 has been formed at FIG. 1C. In other embodiments, device 100 shown in FIG. 1C may undergo further processing.

For example, FIG. 1D depicts device 100′ after additional barrier layer 160 has been formed on TFLC layer 114. Barrier layer 160 is analogous to barrier layer 150. Thus, barrier layer 160 retards or prevents the diffusion of lithium. Further, barrier layer 160 may have structures (e.g. trenches, apertures, a multilayer structure, or other structures) formed therein. Barrier layer 160 may also act as a bonding layer if device 100′ shown in FIG. 1D is to be bonded to another substrate. Thus, a barrier structure including barrier layers 150 and 160 is present in device 100′. In some embodiments, an integrated TFLC photonics device 100′ has been formed if bonding has been completed at FIG. 1D. In other embodiments, device 100′ shown in FIG. 1D may undergo further processing. FIG. 1E depicts electro-optic device 100″ after the device 100′ shown in FIG. 1D has been flipped and bonded to another circuit or substrate C 170. The substrate B 170 (previously functioning as an acceptor substrate) has become a donor substrate. Substrate C 170 may include components that are fabricated therein. In some embodiments, substrate C 170 may include an oxide layer analogous to the SiO₂/BOX layer shown in FIGS. 1A-1D. Because of the barrier structure including barrier layers 150 and 160, Li diffusion into substrate 132 and 170 may be mitigated or prevented. Thus, heterogeneous photonics device 100″ having structures formed on both sides of TFLC layer 114 may be formed.

Thus, heterogeneous integrated photonics device(s) 100, 100′, and/or 100″ have been formed. The device(s) include a Li barrier structure that may be formed from barrier layer 150 (FIG. 1C) or multiple barrier layers 150 and 160 (FIG. 1D and/or FIG. 1E). Because of the use of the barrier structure, performance and reliability of the heterogeneous integrated photonics device(s) 100, 100′, and/or 100″ may be improved. For example, the diffusion of Li in the TFLC 114 layer into the SiO₂ layer 134 and/or into the substrate B 132 (and components thereof) and additional substrate C 170 (and components thereof) may be reduced or eliminated. Consequently, any devices formed using substrate B 132 and/or substrate C 170 may not be adversely affected by Li diffusion. Further, Li contamination in a manufacturing facility due to TFLC layer 114 may be reduced or eliminated. In addition, the performance of components of the electro-optic device formed using TFLC layer 114 may be improved.

FIGS. 1F-1H are diagrams depicting an embodiment of electro-optic device 100′″ during fabrication. For simplicity, not all components are shown and those portions that are shown are not to scale. Further, portions of electro-optic device 100′″ are analogous to electro optic devices 100, 100′, and 100″. These portions are labeled similarly. For example, electro-optic device 100″ includes donor circuit A 110 and an acceptor circuit B 130′″ that are analogous to donor circuit A 110 and acceptor circuit B 130, respectively. Thus, donor circuit A includes donor substrate 112 and TFLC layer 114 that are analogous to those layers of electro-optic devices 100, 100′, and 100″. Similarly, acceptor circuit B 130′″ includes acceptor substrate B 132, an oxide layer 134, and a Li barrier structure 150 analogous to those of acceptor circuit B 130. In addition, acceptor circuit B 140′″ includes an additional oxide layer 135. Oxide layers 134 and 135 are depicted as including silicon dioxide. However, other dielectrics may be used in addition to or in lieu of silicon dioxide. Although shown as part of acceptor circuit B 130′″, oxide layer 135 may be formed on TFLC layer 114 of donor circuit A 110. In such embodiments, barrier layer 150 of FIGS. 1F-1H may function as bonding layer in addition to being a barrier layer.

Li barrier structure 150 of donor circuit B 130″ is a barrier layer and may be termed a barrier layer for photonics device 100″. However, nothing prevents barrier layer 150 from having structures including but not limited to trenches, a multilayer structure, or other structures. Further, although depicted as flat, barrier layer 150 may have another structure, for example due to underlying topology of acceptor circuit B 130. In some embodiments, Li barrier layer 150 is on TFLC layer 114 of donor circuit A 110. In such embodiments, an additional dielectric layer analogous to dielectric layer 135 is between Li barrier layer 150 and TFLC layer 114. In such embodiments, barrier layer 150 of FIGS. 1F-1H may function as bonding layer in addition to being a barrier layer.

Barrier layer 150 substantially retards and/or prevents the diffusion of lithium through barrier layer 150. Further, barrier layer 150 is sufficiently thin that performance of photonics device 100 being formed is not adversely affected. For example, barrier layer 150 may include one or more of titanium nitride, silicon nitride, tantalum nitride, aluminum oxide, and/or silicon oxynitride in the thicknesses described above. Other thicknesses and/or materials may be used. In some embodiments, barrier layer 150 is sufficiently thick to significantly reduce or prevent the formation of pinholes in barrier layer 150. For example, barrier layer 150 may be at least two monolayers (e.g. at least three through ten nanometers) thick. In some embodiments, barrier layer 150 is at least one hundred nanometers thick and not more than five hundred nanometers thick. For example, barrier layer 150 may be at least one hundred and fifty nanometers thick and not more than three hundred nanometers thick. In some embodiments, silicon nitride and silicon oxynitride may be used (or used closer to waveguide 114′) because TaN and TiN are conductive. Consequently, TaN and TiN may be used as or in barrier layers 150 far from structures such as waveguides to reduce eddy currents. In some embodiments, barrier layer 150 is desired to have an index of refraction that differs significantly from the TFLC layer 114 index of refraction. This difference in index of refraction is desired to reduce or prevent the optical mode from being pulled from the TFLC layer 114 into barrier layer 150. In some embodiments, barrier layer 150 may be configured to facilitate coupling of the optical mode in a waveguide formed from TFLC layer 114 to another waveguide and/or another device. In such embodiments, barrier layer 150 is desired to have a higher index of refraction that may be closer to that of TFLC layer 114. In some embodiments, barrier layer 150 is deposited on the SiO₂ layer. In some embodiments, barrier layer 150 is grown on SiO₂ layer 134 (e.g. via nitridization of the SiO₂ layer).

Li barrier layer 150 may thus include or consist of SiN, AlO, SiOxN (silicon oxynitride), TaN, and/or TiN of the desired stoichiometry and thickness to reduce or prevent the diffusion of lithium. For example, barrier layer 150 may include or consist of a low permeability material or a low diffusivity constant material. For example, permeabilities and diffusivities in the range of silicon nitride, aluminum oxide, silicon oxynitride, tantalum nitride, and/or titanium nitride may be considered low. Thus, other material(s) having a low permeability and/or low diffusivity analogous to that of silicon nitride, aluminum oxide, silicon oxynitride, tantalum nitride, and/or titanium nitride might be used.

Further, barrier layer 150 is continuous and is desired to be without pin holes. Barrier layer 150 may thus be considered to partially encapsulate (e.g., placed above or below) TFLC layer 114. Another barrier layer 180 depicted in FIG. 1H may be used in addition to barrier layer 150 to fully encapsulate (e.g., be placed both above and below) TFLC layer 114. Encapsulating TFLC layer 114 may facilitate the 3D integration of the TFLC photonics integrated circuit (PIC) formed using electro-optic device 100′″ into an advanced packaging platform. In some embodiments, barrier layer(s) (not shown in FIGS. 1F-1H) may be provided on the edges of the device. However, in some embodiments, such barrier layer(s) may be omitted. This is because the edges of electro-optic device 100′″ are typically far from patterned TFLC layer 114 or expose only a small portion of patterned TFLC layer 114 (e.g., an edge for coupling light to and/or from the patterned TFLC layer 114). Thus, the edges may be less subject to lithium diffusion and, therefore, less likely to be a source of lithium contamination.

In FIG. 1G, donor circuit A 110 has been flipped and bonded with acceptor circuit B 130′″. Although shown as the same size in FIG. 1G, nothing prevents the donor circuit A 110 and/or acceptor circuit B 130′″ from having different sizes. For example, donor circuit A 110 may be a chiplet, while acceptor circuit B 130 may be one of many circuits on an acceptor wafer 132. In addition, donor substrate 112 has been removed. In some embodiments, the donor substrate 112 may not be completely removed.

FIG. 1H depicts electro-optic device 100′″ after additional processing has been completed. Thus, TFLC layer 114 has been patterned to form waveguide 114′. Other and/or additional structures may have been formed from TFLC layer 114. Also shown are electrodes 137 and cladding 155. Cladding 155 may be a dielectric, such as silicon dioxide. In some embodiments, multiple dielectric layers are provided to form cladding 155. An additional Li barrier layer 180 has also been provided. Barrier layer 180 is analogous to barrier layer 150. Thus, barrier layer 180 may be formed of the same material(s) and/or have a thickness in the same range(s) as barrier layer 150. Barrier layers 150 and 180 are considered to encapsulate structures formed from TFLC layer 114 (e.g. TFLC waveguide 114′). Thus, barrier layers 150 and 180 may extend across the surface of electro-optic device relatively far from TFLC waveguide 114′. In some embodiments, the width(s) of barrier layers 150 and 180 may be at least five, at least ten, at least twenty, or at least fifty multiplied by the width of waveguide 114′. For example, the width(s) of barrier layers 150 and 180 may each be at least five hundred micrometers to at least five thousand micrometers. Other widths are possible. In some embodiments, barrier layers 150 and/or 180 extend to the edges (e.g. horizontally in FIG. 1H and/or out of the plane of the page) of electro-optic device 100′″.

In some embodiments, barrier layer(s) 150 and/or 180 may enhance coupling of waveguide 114′ with an additional waveguide (not shown) or other structure that may be on electro-optic device 100′″ or on another device (not shown). In such embodiments, the barrier layer(s) 150 and/or 180 may function as coupling layer. For example, suppose barrier layer 180 is desired to function as a coupling layer. The distance between barrier layer 180, the composition of barrier layer 180, and/or the thickness of the barrier layer 180 may be configured to enhance the optical coupling between waveguide 114 and barrier layer 180 and/or between barrier layer 180 and the additional waveguide (not shown). The distance between barrier layer 180 and between waveguide 114′ and the additional waveguide may also be configured to improve the coupling.

Thus, barrier layer(s) 150 and 180 may encapsulate TFLC structures such as TFLC waveguide 114′. In particular, the top and bottom of waveguide 114′ are covered by barrier layers 180 and 150. Encapsulating the top and bottom of waveguide 114′ is desirable because along the vertical direction, TFLC waveguides 114′ may be only a few micrometers away from the edge (i.e., top or bottom) of electro-optic device 100′″. The left and right sides may or may not be encapsulated because waveguide 114′ may be a few hundred micrometers away from the chip edge. The front/back (out of the plane of the page) may or may not be encapsulated because waveguide 114′ is thin and relatively narrow compared to the height and width of the TFLC PIC 100′″. Thus, as used herein, encapsulation may include a continuous layer above and below the TFLC material. This encapsulation may control Li contamination to a workable level for the 3D advanced packaging process flow. This may facilitate integration of TFLC photonics device 100′″ with a CMOS platform and/or other devices for which contamination by Li and/or analogous material(s) is an issue.

Further, use of barrier layers, such as barrier layer 180 may enhance the coupling efficiency and reduce the coupling length between TFLC waveguide 114′ in TFLC PIC 100′″ and another waveguide (e.g. a SiN waveguide and/or SiPh PIC). Thus, barrier layer 180 may have relatively high refractive index (close to the refractive indices of SiN and the TFLC material(s) used). For example, SiN, silicon oxynitride, and AlO might be used for barrier layer 180 because they are good diffusion barriers for Li and have appropriate refractive indices (e.g., refractive index of SiN at O-band (1310 nm) is ~2.0, and that of AlO at O-band (1310 nm) is approximately 1.7). Thus, the barrier layers 150 and/or 180 may be configured to enhance coupling (e.g. barrier layer 180 that may be closer to the waveguide of another device) or to reduce coupling (e.g., barrier layer 150 that may be further from the waveguide of the other device).

TFLC photonics device 100′″ includes TFLC optical component(s) 114 and electrodes 135, among other structures. For example, TFLC photonics device 100′″ may include waveguides, splitters, bends, mode converters, polarization beam rotators, and/or other optical components used to transmit and/or modify the optical signal carried by TFLC photonics device 100. Electrodes may be used in conjunction with waveguide(s), for example for optical modulation (e.g. via the electro-optic effect).

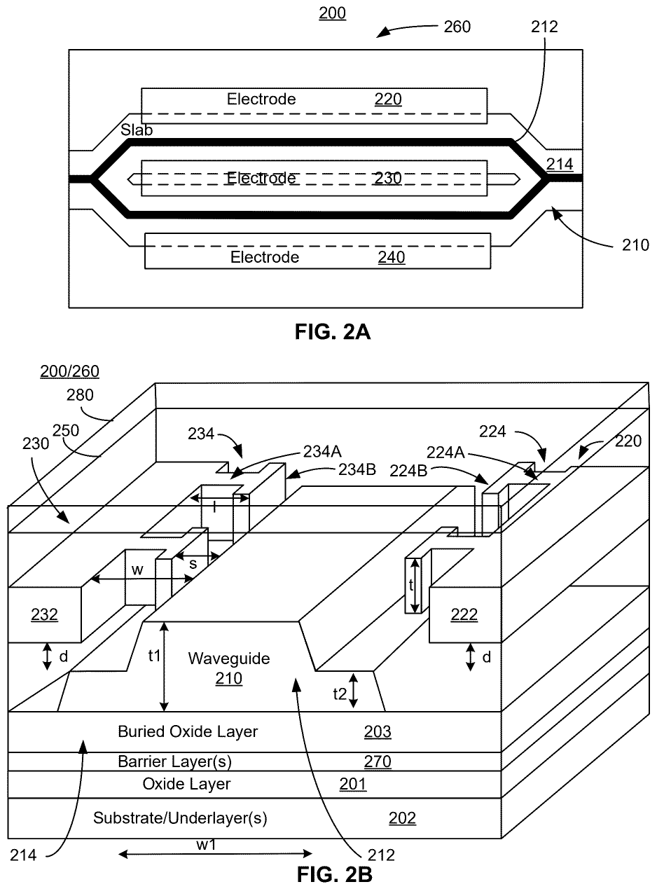

For example, FIGS. 2A-2B depict an embodiment of a portion of TFLC PIC 200 usable in an integrated photonics package, such as integrated photonics packages described herein. For example, photonics device 200 may be used as part or all of a modulator used in TFLC photonics device 100. FIG. 2B is a perspective view of a portion of photonics device 200. FIGS. 2A-2B are not to scale. Only a portion of photonics device 200 is shown. Photonics device 200 may include other and/or additional structures that are not shown for simplicity. Further, although particular configurations are shown, other configurations are possible.

Photonics device 200 is on a substrate structure that includes substrate 202 and buried oxide (BOX) layer 203. In some embodiments, substrate 202 is a silicon substrate. Substrate 202 may also include other layers. In some embodiments, substrate 202 may be glass, quartz, silicon-on-insulator, and/or other low microwave loss dielectrics. Substrate 202 may be one hundred micrometers or more thick. BOX layer 203 may be a silicon dioxide layer. In some embodiments, BOX layer 203 may be at least three micrometers thick and not more than fifteen micrometers thick. In some embodiments, the substrate structure may be configured differently. Also shown is cladding 250, which may be formed of silicon dioxide.

Photonics device 200 includes waveguide 210 and electrodes 220, 230, and 240. In some embodiments, photonics device 200 may be configured as or include a modulator (or portion thereof). Thus, photonics device 200 may be considered to include modulation region 260. Other regions, such as a bend region, may be present. Modulator 200 is shown as configured as a Mach-Zehnder modulator. Other configurations for phase and/or amplitude modulation are possible. For clarity, only the portion of electrodes 220, 230, and 240 proximate to waveguide 210 are shown. Stated differently, electrodes 220, 230, and 240 are shown in modulation region 260.

Waveguide 210 may be considered to include ridge 212 as well as slab 214. Ridge 212 has a height, t1, greater than the height, t2, of slab 214. Although shown as rectangles, ridge 212 and/or slab 214 have other shapes, such as trapezoids and/or other analogous shapes. In addition, slap 212 may terminate closer to ridge 214 than at least a portion of electrode(s) 220 and/or 230. Photonics device 200 includes electro-optic optic material(s), such as TFLC materials (e.g. TFLN and/or TFLT). More specifically, ridge 212 and slab 214 include electro-optic materials, such as TFLC materials. In some embodiments, the waveguide 210 consists of TFLC materials such as TFLN and/or TFLT. In the embodiment shown, ridge 212 and slab 214 are formed of the same material. In some embodiments, ridge 212 and slab 214 may include different materials. Waveguide 210, and more particularly ridge 212, may be used to propagate the optical signal. The optical mode may be well confined to ridge 212 and/or ridge 212 in combination with a portion of nearby slab 214. Slab 214 provides increased electro-optic modulation efficiency. In particular, slab 214 aids in directing the electric field generated by the signal(s) in electrodes 220, 230, and 240 to optical mode 213 in modulation region 260. Thus, a higher modulation for a given electric field may be obtained. As a result, V-pi (and V-pi-L) may be reduced.

In some embodiments, the TFLC layer from which TFLC waveguide 210 is formed has a thickness of less than two micrometers or less than one micrometer. Thus, TFLC waveguide 210 may have a thickness of less than two micrometers, less than one micrometers, less than six hundred nanometers, less than five hundred nanometers, or less than four hundred nanometers. The thickness of TFLC waveguide 210 may be at least fifty nanometers. In some embodiments, the TFLC layer has a thickness of at least two hundred and fifty nanometers. For example, TFLC waveguide 210 may be nominally three hundred nanometers or three hundred and fifty nanometers thick with, for example, a 10-15 nanometer variation. The thickness of TFLC waveguide 210 (e.g. t1, to the top of ridge 112) may be not more than three hundred nanometers, not more than three hundred and fifty nanometers, not more than four hundred nanometers, not more than five hundred nanometers, not more than six hundred nanometers, not more than seven hundred nanometers, not more than one micrometer, not more than 1.5 micrometer, and/or not more than two micrometers. In some embodiments, the thickness of TFLC waveguide 210 may be at least more than three hundred nanometers, at least three hundred and fifty nanometers, at least four hundred nanometers, at least five hundred nanometers, at least six hundred nanometers, at least seven hundred nanometers, at least one micrometer, or at least 1.5 micrometer.

The etches also form the sidewall angles for TFLC waveguide 110. The sidewall angles for ridge 112 and/or slab 114 may not exceed ninety degrees and are typically less than ninety degrees (e.g., not quite vertical). For example, the sidewall angles may be less than 85 degrees, less than 80 degrees, less than 75 degrees, and/or less than 70 degrees The sidewall angles may be desired to be steep. For example, the sidewall angles may be at least forty-five degrees, at least fifty-five degrees, or at least sixty degrees. The sidewalls may also have a lower surface roughness (e.g., less than ten nanometers), allowing for low optical losses in waveguides 110 of TFLC PIC 100. TFLC waveguide 110 has a width (e.g., a smallest feature size), w. In some embodiments, the width of TFLC waveguide (i.e., TFLC optical structure) 110 is not more than one micrometer. This may be the smallest feature size for the TFLC waveguide 110. In some embodiments, the smallest feature size in the TFLC waveguide 110 is not more five hundred nanometers. In some such embodiments, the smallest feature size (e.g., the smallest width, w1) of TFLC waveguide 110 is not more than two micrometers or not more than one micrometer.

Electrodes 220, 230, and 240 may carry electrode signals used to modulate the optical signals (e.g. light) carried by waveguide 210 via electro-optic modulation. Electrode(s) 220 and/or 230 are configured to carry a traveling wave (e.g. a microwave or RF electrode signal) that modulates the optical signal carried by waveguide 210 via the electro-optic effect. For example, the electrode signals may provide electro-optic modulation up to frequencies of 100 GHz, 200 GHz, 500 GHZ or higher. In some embodiments, modulator 210 may provide modulation from at or near DC to frequencies of 100 GHz, 200 GHz, 500 GHz, or more. The modulation may also have a wide window, for example an operation bandwidth of at least 20 GHz. Electrode signals carried by electrodes 220, 230, and 240 may be configured in a variety of manners. For example, electrode 230 may carry a microwave signal, while electrodes 220 and 240 are ground. Electrode 230 may carry a signal of a first polarity, while electrodes 220 and 240 carry signals of opposite polarity (i.e. in a differential configuration). Other configurations (including but not limited to another number of electrodes) are possible.

Electrodes 220, 230, and/or 240 may include extensions. Embodiments of analogous electrodes may be found in co-pending U.S. patent application Ser. No. 17/843,906, entitled ELECTRO-OPTIC DEVICES HAVING ENGINEERED ELECTRODES, which is a continuation of U.S. patent application Ser. No. 17/102,047 entitled ELECTRO-OPTIC DEVICES HAVING ENGINEERED ELECTRODES, filed Nov. 23, 2020, which claims priority to U.S. Provisional Patent Application No. 62/941,139 entitled THIN-FILM ELECTRO-OPTIC MODULATORS filed Nov. 27, 2019, U.S. Provisional Patent Application No. 63/033,666 entitled HIGH PERFORMANCE OPTICAL MODULATORS filed Jun. 2, 2020, and U.S. Provisional Patent Application No. 63/112,867 entitled BREAKING VOLTAGE-BANDWIDTH LIMIT IN INTEGRATED LITHIUM NIOBATE MODULATORS USING MICRO-STRUCTURED ELECTRODES filed Nov. 12, 2020, all of which are incorporated herein by reference for all purposes. In other embodiments, extensions may be omitted from some or all of electrodes 220, 230, and/or 240. Electrodes 220, 230, and 240 may carry differential electrical signals, a single electrical signal (e.g. a signal and ground), or other signal(s).

Electrode 230 includes a channel region 232 and extensions 234 (of which only one is labeled in FIG. 2B). Similarly, electrode 220 includes channel region 222 and extensions 224 (of which only one is labeled in FIG. 2B). In some embodiments, extensions 224 or 234 may be omitted from electrode 220 or electrode 230, respectively. Extensions 224 and 234 may be closer to ridge 212 than channel region 222 and 232, respectively, are. For example, the distance s from extensions 224 and 234 to waveguide ridge 212 is less than the distance w from channels 222 and 232 to waveguide ridge 212. Extensions 224 may be closer to electrode 230 (e.g. extensions 234 and/or channel 232) than channel 222 is. Similarly, extensions 234 may be closer to electrode 220 e.g. extensions 224 and/or channel 222) than channel 232 is.

Extensions 224 and 234 are in proximity to ridge 212. For example, extensions 224 and 234 are a vertical distance, d from slab 214 of TFLC waveguide 210. The vertical distance to TFLC waveguide 210 may depend upon the cladding 250 used. The distance d is highly customizable in some cases. For example, d may range from zero (or less if electrodes 220 and 230 contact or are embedded in slab portion 214) to greater than the height of ridge 212. In embodiments in which slab 214 terminates closer to ridge 212 than channel regions 222 and 232, d may be zero (same level as the top surface of slab 214), positive (further from substrate 202 than the top surface of slab 214), or negative (further from substrate 202 than the top surface of slab 214). However, d is generally still desired to be sufficiently small that electrodes 220 and 230 can apply the desired electric field to ridge 212. Extensions 224 and 234 are also a distance, s, from ridge 212. In some embodiments, s<0 (i.e., extensions 224 and/or 234 may extend over the top of ridge 212 or below waveguide 210). Extensions 224 and 234 are desired to be sufficiently close to TFLC waveguide 210 (e.g. close to ridge 212) that the desired electric field and index of refraction change can be achieved. However, extensions 224 and 234 are desired to be sufficiently far from TFLC waveguide 210 (e.g. from ridge 212) that their presence does not result in undue optical losses. Although shown next to ridge 212, extensions 224 and/or 234 may extend above and/or below ridge 212.

In the embodiment shown, extensions 224 have a connecting portion 224A and a retrograde portion 224B. Retrograde portion 224B is so named because a part of retrograde portion may be antiparallel to the direction of signal transmission through electrode 220. Similarly, extensions 234 have a connecting portion 234A and a retrograde portion 234B. Thus, extensions 224 and 234 have a “T”-shape. In some embodiments, other shapes are possible. For example, extensions 224 and/or 234 may have an “L”-shape, may omit the retrograde portion, may be rectangular, trapezoidal, parallelogram-shaped, may partially or fully wrap around a portion of ridge 212, and/or have another shape. Similarly, channel regions 222 and/or 232, which are shown as having a rectangular cross-section, may have another shape. Further, extensions 224 and/or 234 may be different sizes. Although all extensions 224 and 234 are shown as the same distance from ridge 212, some of extensions 224 and/or some of extensions 234 may be different distances from ridge 212. Channel regions 222 and/or 232 may also have a varying size.

Also indicated in FIG. 2B is thickness, t, of extensions 224 and 234. In the embodiment shown, channels 222 and 232 have the same thickness. In some embodiments, the thickness of extensions 224 and/or 234 may vary. For example, extensions 224 may be thinner (or thicker) than extensions 234. Further, different extensions 224 may have different thicknesses. Similarly, different extensions 234 may have different thicknesses. Extensions 224 and/or 234 may also have a different thickness than channels 222 and/or 232. For example, extensions 224 and/or 234 may be thinner (or thicker) than channels 222 and/or 232. Different portions of extensions 224 and/or 234 may also have different thicknesses. For example, retrograde portions 224B and/or 234B may be thinner (or thicker) than connecting portions 224A and/or 234B. Thus, TFLC PICs 200 and 100 may have a variety of configurations, components, and functions. Performance of TFLC PICs 200 and 100 may be superior to that of other, non-TFLC PICs.

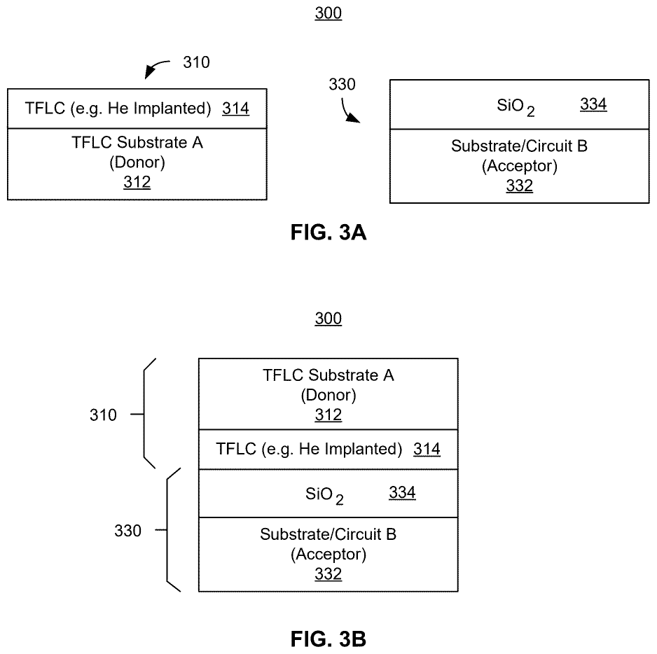

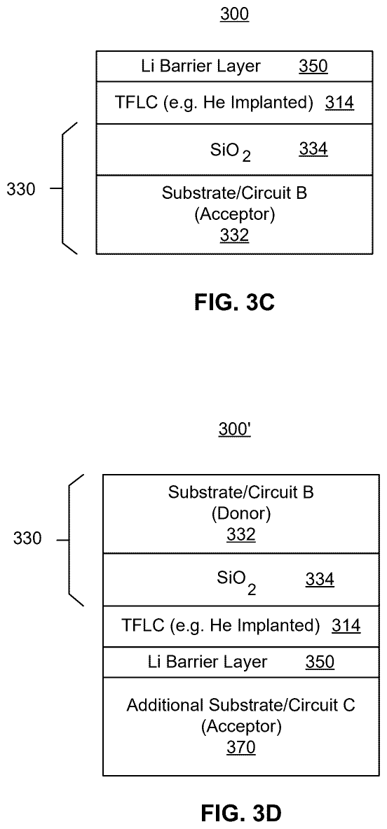

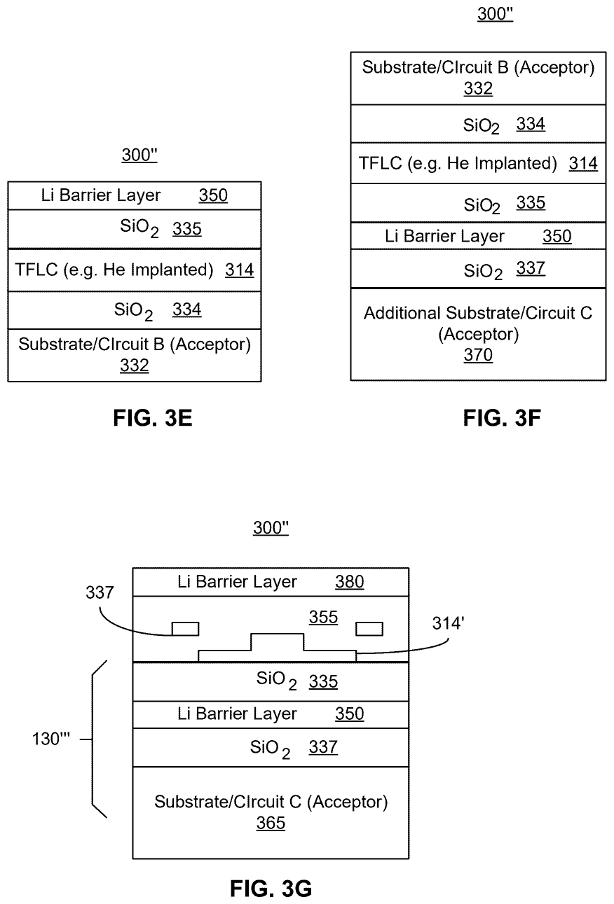

FIGS. 3A-3G are diagrams depicting embodiments of electro-optic devices 300, 300′1 and 300″ during fabrication. For simplicity, not all components are shown and those portions that are shown are not to scale. In the embodiment shown in FIGS. 3A-3D, donor circuit 310 and an acceptor circuit 330 are utilized. Donor circuit 310 includes a donor substrate 312 and TFLC material 314, which is depicted as a layer. Acceptor circuit 330 includes acceptor substrate 332 and oxide layer 334. TFLC layer 314 is on donor substrate, or wafer, 312. In the embodiment shown, TFLC layer 314 is a TFLN layer, which may be implanted with He. Other electro-optic layers that include Li might be used in other embodiments. For example, LT may also be used. Donor circuit A 310 and acceptor circuit B 330 are analogous to donor circuit 110 and acceptor circuit 130 of in FIG. 1A except that neither the donor circuit A nor the acceptor circuit B includes a barrier structure analogous to barrier structure 150.

Acceptor substrate B 332, or wafer, may be a Si wafer on which an SiO₂ (or other appropriate oxide such as borophosphosilicate glass) layer 334 is provided. Because of its position in the final integrated circuit, oxide layer 334 may be considered a BOX layer. In some embodiments, structures, such as silicon waveguides or other silicon photonics structures and/or CMOS components, may be formed in acceptor substrate 332. In other embodiments, the acceptor substrate 332 may be a blank substrate.

FIG. 3B indicates that donor circuit 310 A has been flipped and bonded with acceptor circuit B 330. Although shown as the same size in FIG. 3B, nothing prevents the donor and acceptor circuits 310 and 330 from having different sizes. For example, donor circuit 310 may be a chiplet, while the acceptor circuit 330 may be one of many circuits on an acceptor wafer (e.g. a SiPh wafer). However, because barrier layer 150 used in FIGS. 1-1E has been omitted, the BOX layer (e.g. SiO₂) 334 may be desired to be thicker to prevent Li diffusion into substrate B 332.

FIG. 3C indicates that donor substrate 312 has been removed. Barrier structure 350 has also been provided. Barrier structure 350 is depicted and described herein as a layer. However, barrier structure 350 may include structures fabricated therein (e.g. trenches, apertures, a multilayer structure, or other structures). In some embodiments, barrier layer 350 shown in FIG. 3C is analogous to barrier layer 150 and/or 160 shown in FIGS. 1A-1H. Barrier layer 150 of FIG. 3C may function as bonding layer in addition to being a barrier layer. In some embodiments, an integrated TFLC photonics device 300 has been formed. In other embodiments, the circuit 300 shown in FIG. 3C may undergo further processing. For example, FIG. 3D depicts the electro-optic device 300′ after device 300 shown in FIG. 3C has been flipped and bonded to another circuit or substrate C 370. Substrate B 332 has become a donor substrate. Substrate C 370 may be analogous to substrate 170. Thus, substrate C 370 may include components that are fabricated therein. In some embodiments, substrate C 370 may include an oxide layer analogous to the SiO₂/BOX layer shown in FIGS. 1A-1E.

FIGS. 3E-3G depict an embodiment of TFLC electro-optic device 300″ analogous to TFLC device 300 depicted in FIG. 3C. However, dielectric layer 335 is between barrier structure 350 and TFLC layer 314. In the embodiment shown, dielectric layer 335 is a silicon dioxide layer. In FIG. 3F, the circuit 330′ has been flipped and bonded to additional acceptor substrate C 370 analogous to substrate C 370 of FIG. 3D. However, additional dielectric layer 339 is provided between barrier structure 350 and substrate C 370. FIG. 3G depicts TFLC electro-optic device 300″ after dielectric layer 334 has been removed and TFLC layer 314 has been patterned to form waveguide 314′. In addition, cladding 355 and electrodes 337 have been formed. An additional lithium barrier structure 380 has been formed. Barrier structure 380 is analogous to barrier structure 350. Thus, TFLC electro-optic device 300″ having barrier layers 350 and 380 that encapsulate TFLC waveguide 314′ has been formed. TFLC electro-optic device 300″ is analogous to TFLC electro-optic device 100′″. Other techniques for forming analogous TFLC photonics devices may be used. TFLC electro-optic device 300″ may share the benefits of TFLC electro-optic device 100′″.

Thus, heterogeneous integrated photonics circuit(s) 300, 300′, and/or 300″ have been formed. The circuit(s) include barrier structure 350 that may be formed as a barrier layer 350 (FIG. 3C and/or FIG. 3D). Because of the use of barrier structure 350, performance and reliability of the heterogeneous integrated photonics device(s) 300, 300′, and/or 300″ may be improved. In particular, benefits analogous to those described for the photonics devices 100, 100′, 100″ and/or 100′″ of FIGS. 1A-1H may be realized. For example, Li contamination in a manufacturing facility due to TFLN layer 314 may be reduced or eliminated. Further, the stoichiometry of TFLN layer 314 may be closer to what is desired. Thus, the optical properties of TFLN layer 314 may be preserved and performance of components of the electro-optic device(s) 300, 300′, and/or 300″ formed using TFLN layer 314 may be improved. Further, TFLC electro-optic device 300″ having barrier layers 350 and 380 that encapsulate waveguide 314 may be integrated with other devices that are sensitive to lithium contamination. In addition, barrier layer 380 and/or barrier layer 350 may be configured to improve coupling between waveguide 314′ and another waveguide (not shown) for another device.

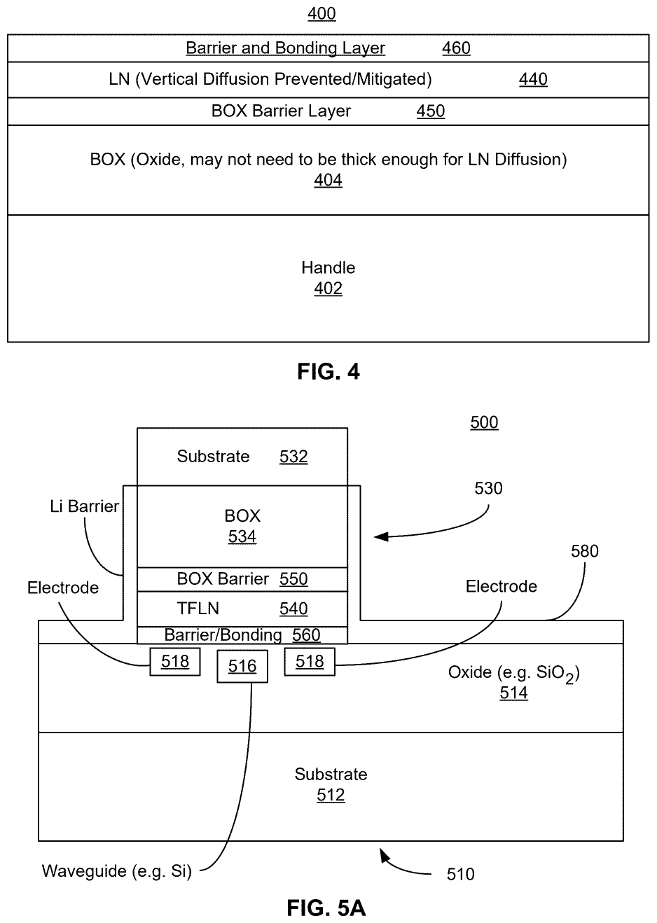

FIG. 4 depicts another embodiment of electro-optic device 400 including a lithium-containing TFEO material on an insulator. More specifically, electro-optic device 400 is a TFLN on insulator (TFLNOI) circuit. In some embodiments, TFLNOI circuit 400 shown in FIG. 4 undergoes further processing to form a final device. TFLNOI circuit 400 includes handle wafer 402, BOX layer 404, BOX barrier layer 450, TFLN layer 440, and barrier and bonding layer 460. Handle wafer 402 may be a silicon wafer. In some embodiments, structures are formed in handle wafer 402. In other embodiments, handle wafer 402 may not have structures formed therein. In some embodiments, BOX barrier layer 450 and barrier and bonding layer 460 are each Li barrier layers such as those described herein (e.g. barrier layers 150, 160, and 350. For example, layers 450 and 460 may include or consist of TaN, TiN, SiN, SiOxN (silicon oxynitride) of the desired stoichiometry and thickness. Thus, the barrier structure for TFLNOI circuit 400 4 may include both BOX barrier layer 450 and barrier and bonding layer 460. In some embodiments, BOX barrier layer 450 and/or barrier and bonding layer 460 are desired to be insulating. Thus, Li barrier layers 450 and 460 of FIG. 4 may be SiN and/or SiOxN.

In some embodiments, BOX barrier layer 450 is deposited. For example, SiN may be deposited and, in some cases, densified. In some embodiments, box barrier layer 450 may be formed by nitridizing a silicon dioxide BOX layer. When forming BOX barrier layer 450, high temperature anneals and/or other processes that may adversely affect TFLN layer 440 may be used. This is because TFLN layer 440 has not yet been provided. In some embodiments, BOX barrier layer 450 is desired to be thin. A thinner BOX barrier layer 450 may be desired because the indexes of refraction are similar for TFLN and SiN and/or some stoichiometries of SiOxN. In some embodiments, a thin layer of oxide such as SiO₂ (not shown in FIG. 4), is provided on top of BOX barrier 450 for improved bonding to TFLN layer 440.

After formation of BOX barrier layer 450, TFLN layer 440 may be provided. TFLN layer 440 may be bonded to BOX barrier layer 450 in a manner analogous to that described with respect to FIGS. 1A-1E. Barrier and bonding layer 460 may then be provided. Barrier and bonding layer 460 may be deposited on TFLN layer 440. In some embodiments, TFLN layer 440 may be doped prior to deposition of barrier and bonding layer 450 to improve the stoichiometry of the TFLN after encapsulation by barrier and bonding layer 460. In addition, a charge bleed layer (not shown in FIG. 4) may be provided prior to encapsulation.

TFLNOI circuit 400 of FIG. 4 may share the benefits of the heterogeneous circuits described with respect to FIGS. 1A-1E and FIGS. 3A-3D. Vertical out-diffusion of Li may be reduced or prevented from both top and bottom surface of TFLN layer 440. In some embodiments, TFLN layer 440 may be further processed. For example, TFLN layer 440 may be etched to form waveguides before and/or after barrier and bonding layer 460 is provided.

Thus, TFLNOI circuit 400 has been formed. The Li barrier structure is formed by BOX barrier layer 450 and barrier and bonding layer 460. Because of the use of the Li barrier structure, performance and reliability of a heterogeneous integrated photonics device utilizing TFLNOI circuit 400 of FIG. 4 may be improved. Li diffusion into other components (e.g. those above or below the Li barrier layers 450 and 460) may be reduced or eliminated. Li contamination in a manufacturing facility due to TFLN layer 440 may be reduced or eliminated. Further, the stoichiometry of TFLN layer 440 may be closer to what is desired. Thus, the optical properties of TFLN layer 440 may be preserved and performance of components of the electro-optic device formed using TFLN 440 layer may be improved.

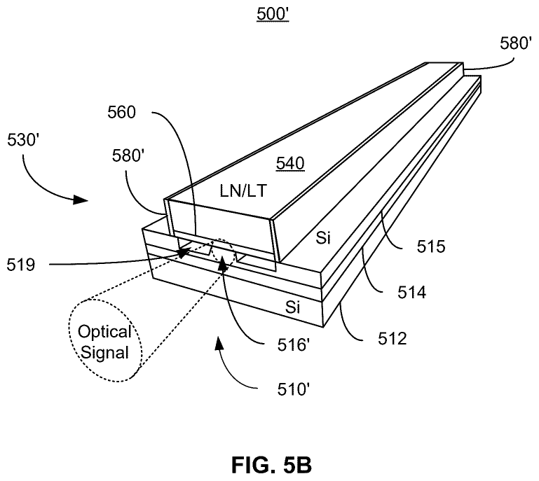

FIGS. 5A-5B depict embodiments of heterogeneous integrated devices 500 and 500′ that include electro-optic layers having Li. In the embodiments shown, the electro-optic devices 500 and 500′ include lithium-containing TFEO layers 540. In some embodiments, TFLN is used for layer 540. In other embodiments, another Li-containing electro-optic material such as LT may be used. Thus, the lithium-containing TFEO layer 540 is described as LN/LT or TFLN layer 540. Heterogeneous integrated electro-optic device 500 of FIG. 5A includes TFLN chiplet 530 (i.e. a chiplet including TFLN electro-optic layer 540) and a SiPh integrated circuit 510. SiPh chip 510 is an SOI integrated circuit that includes silicon substrate 512 and oxide layer 512, such as SiO₂. In the embodiment shown, SiPh integrated circuit 510 also includes silicon waveguide 516 and electrodes 518. In some embodiments, the confinement of Si waveguide 516 may be tailored. For example, waveguide 516 may be made smaller so that the mode expands. This may aid in coupling with TFLN layer 550 of TFLN chiplet 530. However, waveguide 516 may still be sufficiently large that the mode does not extend to electrodes 518. In other embodiments, additional and/or other components may be included.

TFLN chiplet 530 includes barrier/bonding layer 560, TFLN layer 540, BOX barrier layer 550, BOX layer 534, and substrate 532 that are analogous to barrier and bonding layer 460, TFLN layer 440, BOX barrier layer 450, BOX layer 404, and/or substrate 402 depicted in FIG. 4. Thus, TFLN chiplet 530 shown in FIG. 5A may be singulated from a wafer 512 analogous to that shown in FIG. 4. In the embodiment shown, TFLN chiplet 5230 as unpatterned TFLN layer 540. In other embodiments, TFLN layer 540 may be patterned and/or other components may be included. In some embodiments, silicon oxynitride may be utilized for barrier/bonding layer 560 and/or BOX barrier layer 550. Use of silicon oxynitride allows for tailoring of the indexes of refraction of barrier/bonding and BOX barrier layers 560 and 550. Consequently, a larger difference in the indexes of refraction between TFLN layer 540 and the barrier layers 560 and 550 may be achieved. In other embodiments, SiN and/or other Li barriers may be used in addition to or in lieu of silicon oxynitride. In some embodiments, a somewhat thinner barrier/bonding layer 560 and/or BOX barrier layer (e.g. at least thirty nanometers or at least fifty nanometers of SiN) 550 may be used. Such thinner barrier layers 550 and/or 560 may allow some diffusion of Li. However, diffusion of Li may still be retarded or eliminated. In some embodiments, a layer of indium-tin-oxide (ITO) may be provided as a bleed layer. The bleed layer may be on either side (e.g. above or below) the TFLN layer.

Heterogeneous integrated device 500 of FIG. 5A also includes additional Li barrier layers 580 that cover at least the sides of the TFLN layer 540. Barrier layers 580 are analogous to barrier layers 550 and 560, and thus to barrier layers 150, 160, 350, 450, and/or 460. In the embodiment shown, the additional barrier layers 580 cover the sides of TFLN chiplet 530 and the top surface of the SiPh integrated circuit 510. In other embodiments, additional barrier layer 580 may cover only the sides of the TFLN chiplet 530 or a combination of the sides of the TFLN chiplet 530 and a portion of the top surface of SiPh integrated circuit 510 in proximity to TFLN chiplet 510. In some embodiments, different Li barrier layers may be used in proximity to the TFLN layer and far from the TFLN layer. For example, SiN and/or SiOxN may be used on and near TFLN chiplet 530, while TiN and/or TaN (e.g. as little as ten nanometers of ALD deposited TiN) may be used further from waveguide 516. Barrier layers 560 in proximity to waveguide 516 are generally desired to be insulating. Thus, in some embodiments, SiN and/or SiOxN are used for BOX barrier layer 560 and barrier/bonding layer 550. The additional barrier layers 580 might be conductive, insulating, or both (e.g. insulating in some regions and conductive in other regions. The barrier structure in FIG. 5A thus includes the barrier/bonding layer 560, BOX barrier layer 550, and additional barrier layers 580.

FIG. 5B is a perspective view of a heterogeneous integrated electro-optic device 500′ including a SiPh integrated circuit 510′ and an TFLN chiplet 530′. Heterogeneous integrated device 500′ depicted in FIG. 5B is analogous to that shown in FIG. 5A. Thus, heterogeneous integrated electro-optic device 500′ includes Si substrate 512, oxide 514, Si waveguide 516′, additional oxide 519 as part of SiPh integrated circuit 510′. Heterogeneous integrated electro-optic device 500′ also includes TFLN chiplet 530′ including TFLN (or other lithium-containing TFEO layer) 540 and barrier layer 560. However, additional Li barrier layers 580′ reside only on the sides of the TFLN chiplet 530′. In addition, the optical signal carried by the silicon waveguide is shown.

Thus, heterogeneous integrated TFLN-SiP devices 500 and 500′ have been formed. The circuit(s) include TFLN chiplets 510/510′ having a Li barrier structure. Because of the use of the Li barrier structure, performance and reliability of the heterogeneous integrated TFLN-SiP device 500 and/or 500′ may be improved. In particular, benefits analogous to those described for the photonics devices of FIGS. 1A-1E may be realized. For example, Li contamination in a manufacturing facility due to the TFLN layer ′540 and/or 540′ may be reduced or eliminated. Further, the stoichiometry of the TFLN layer 540 and/or 540′ may be closer to what is desired. Thus, the optical properties of the TFLN layer may be preserved and performance of components of the electro-optic device formed using the TFLN layer may be improved.

FIGS. 6A-6B depict embodiments of TFLC PICs 600 and 600′ that utilize barrier structures. Referring to FIG. 6A, cross-sectional views of TFLC photonics integrated circuit 600 are shown. TFLC PIC 600 includes dielectric layers 601 and 603, waveguide 610, electrodes 620 and 630, cladding 650, and dielectric 690 as well as lithium barrier structures 670 and 680. Underlying substrates are not shown for simplicity. TFLC photonics device 600 is analogous to devices 100′″′, 200, and 300″. Thus, dielectric layers 601, 603, 650, and 690 are analogous to layers 134, 201, 337, 135, 203, 335, 155, 250, and 355. For example, dielectric layers 601, 603, 650, and 690 may include or be formed of silicon dioxide. Waveguide 610 is a TFLC waveguide including ridge 612 and slab portion 614 in at least some regions. In the embodiment shown, waveguide 610 may also be a strip waveguide 610 in some regions. In such regions, slab 614 may be etched away and/or ridge 612 thinned. Waveguide 610 is analogous to waveguides 114′, 210, and 314′. In some embodiments, the thickness of ridge 612, H3, is at least two hundred nanometers and not more than six hundred nanometers. In some embodiments, the thickness of slab portion 614, H4 is at least one hundred nanometers and not more than four hundred nanometers. Other thicknesses for the ridge 612 and/or slab portion 614 are possible. In some embodiments, the width of ridge 612, W1, is at least one micrometer and not more than two micrometers. In some embodiments, the width of slab region 214, W2, is at least five micrometers and not more than twenty micrometers. For example, W2 may be at least nine micrometers and not more than eleven micrometers. The width of the strip waveguide portion of waveguide 610, W3, may be at least 180 nm and not more than 2 μm. Other dimensions for waveguide 610 are possible.

Barrier structures 670 and 680 (also termed barrier layers 670 and 680) are analogous to barrier layers 150, 270, and 350 and barrier layers 180, 280, and 380. Thus, barrier layers 670 and 680 are continuous layers that encapsulate (e.g., are placed above and below) TFLC waveguide 610. Barrier layers 670 and 680 may thus allow for 3D integration of the TFLN/TFLT PIC into the advanced packaging platform. Barrier layers 670 and 680 substantially retard and/or prevents the diffusion of lithium through barrier layers 670 and 680. Further, barrier layers 670 and 680 are sufficiently thin that performance of photonics device 600 is not adversely affected. For example, the thickness of barrier layer 670, H6 may be at least one hundred nanometers and not more than five hundred nanometers. In some embodiments, H6 may be at least one hundred and fifty nanometers and not more than three hundred nanometers. Other dimensions are possible. In addition, barrier structures 670 and 680 are shown as substantially flat. For example, a chemical mechanical polish (CMP) may be performed prior to formation of barrier layer 680. Consequently, the separation between barrier layers 670 and 680 may be relatively constant.

Barrier layers 670 and 680 may include one or more of titanium nitride, silicon nitride, tantalum nitride, aluminum oxide, and/or silicon oxynitride in the thicknesses described above. Other thicknesses and/or materials may be used. In some embodiments, barrier layers 670 and 680 are each sufficiently thick to significantly reduce or prevent the formation of pinholes in barrier layers 670 and 680. Thus, apertures are not inadvertently formed in barrier layers 670 and 680. Although not shown, vias may be formed in barrier layer 680 in order to connect electrodes 620 and/or 630 to pads (not shown). Thus, barrier layers 670 and 680 may be considered to contain lithium in the region between barrier layers 670 and 680. In some embodiments, this region has a height, H1 of at least one micrometer and not more than ten micrometers. In some embodiments, H1 is at least 3.5 micrometers and not more than 4.5 micrometers. In some embodiments, the total height, H2, of the portion of TFLC PIC 600 shown is at least two micrometers and not more than ten micrometers. For example, H2 may be at least 5.5 micrometers and not more than 6.5 micrometers. Thus, the region between barrier layers 670 and 680 is a significant fraction of TFLC PIC 600.

In some embodiments, barrier layer(s) 670 and/or 680 may be provided to the edges of the device. In some embodiments, barrier layers 670 and 680 may not extend that far. However, barrier layers 670 and 680 may still be desired to extend relatively far from waveguide 610. For example, width, W4 of layers 670 and 680 may be at least five hundred micrometers and not more than five thousand micrometers. In some embodiments, the width of barrier layers 670 and/of 680 is at least ten, at least fifteen, or at least twenty multiplied by the width of waveguide 610.

In some embodiments, the side edges of TFLC electro-optic device 600 are encapsulated by barrier layers analogous to barrier layers 670 and 680. For example, FIG. 6B depicts cross-sectional views of TFLC photonics device 600′. Photonics device 600′ is analogous to photonics device 600, but also includes barrier layers 672 and 674. Barrier layers 672 and 674 are analogous to barrier layers 670 and 680, but have been deposited or grown on the side edges of TFLC photonics device 600′. In some embodiments, analogous barrier layers may be provided on the front and back edges (e.g. the edges that are parallel to the plane of the page in FIG. 6B). However, in some embodiments (e.g., TFLC PIC 600), such barrier layer(s) may be omitted. This is because the edges of electro-optic device 600 are typically far from the edges of waveguide 610 and because waveguide 610 occupies only a small fraction, if any, of the edges. Thus, the edges may be less subject to lithium diffusion and, therefore, less likely to be a source of lithium contamination.

In some embodiments, barrier layer(s) 670 and/or 680 of TFLC PICs 600 and 600′ may enhance coupling of waveguide 610 with an additional waveguide (not shown) or other structure that may be on TFLC PICs 600 and 600′ or on another device (not shown). In such embodiments, the barrier layer(s) 670 and/or 680 may function as coupling layer. For example, suppose barrier layer 680 is desired to function as a coupling layer. The distance between barrier layer 680, the composition of barrier layer 680, and/or the thickness of the barrier layer 680 may be configured to enhance the optical coupling between waveguide 610 and barrier layer 680 and/or between barrier layer 680 and the additional waveguide (not shown). For example, the refractive index of barrier layer 680 may be closer to the refractive index of waveguide 610. Thus, the refractive index of barrier layer 680 in such embodiments may be higher than that of cladding 650. The distance between barrier layer 680 and between waveguide 610 and the additional waveguide may also be configured to improve the coupling. For example, barrier layer 680 may be configured to such that the coupling loss between waveguide 610 and another waveguide (e.g., of another device) is not more than 0.1 dB for a constrained coupling length of less than 300 nanometers or less than 200 micrometers and a separation between waveguide 610 and the other waveguide of greater than one micrometer.

Thus, TFLC PICs 600 and 600′ may share the benefits of electro-optic device 100′″′, 200, and 300″ as well as electro-optic devices 100, 100′, 100″, 300, and 300′. The use of barrier layers 670 and 680 may not only reduce lithium contamination but also improve optical coupling with other devices.

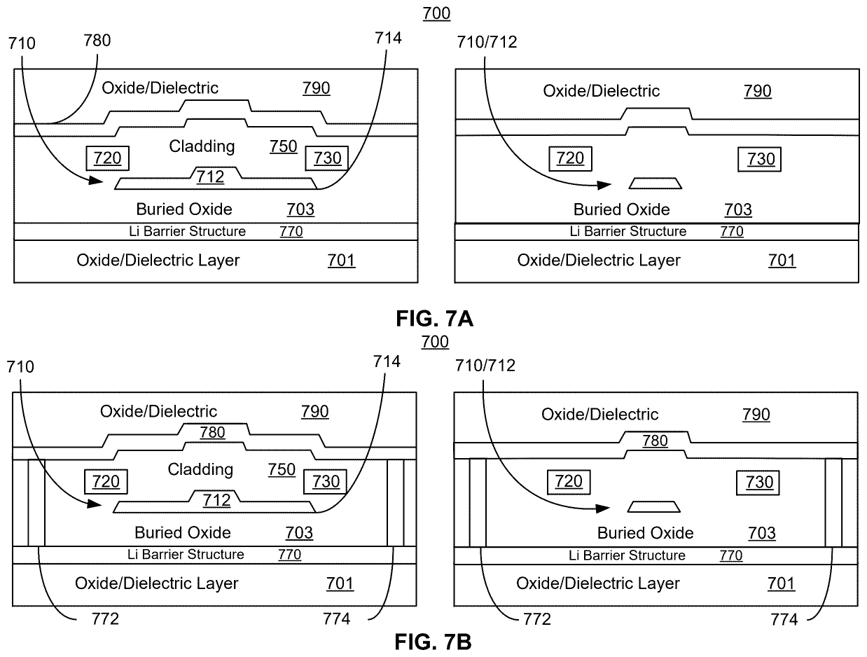

FIGS. 7A-7B depict embodiments of TFLC PICs 700 and 700′ that utilize barrier structures. TFLC PICS 700 and 700′ are analogous to TFLC PICs 600 and 600′, respectively. TFLC photonics PICs 700 and 700′ include dielectric layers 701 and 703, waveguide 710, electrodes 720 and 730, cladding 750, and dielectric 790 as well as lithium barrier structures 770 and 780 that are analogous to dielectric layers 601 and 603, waveguide 610, electrodes 620 and 630, cladding 650, and dielectric 690 as well as lithium barrier structures 670 and 680, respectively. Thus, the structure and function of dielectric layers 701 and 703, waveguide 710, electrodes 720 and 730, cladding 750, and dielectric 790 as well as lithium barrier structures 770 and 780 that are analogous to corresponding portions of TFLC PICs 600 and 600′. In addition, TFLC PIC 700′ includes barrier layers 772 and 774 that are analogous to barrier layers 672 and 674. In the embodiment shown, barrier layers 772 and 774 have been moved in slightly from the edges TFLC PIC 700′. In other embodiments, barrier layer 772 and 774 may be placed at the edges of TFLC photonics device 700′.

In addition, barrier layer 780 matches the underlying topology of TFLC PICs 700 and 700′. This may be because a CMP or other analogous planarization process is not performed prior to formation of barrier layers 780. However, barrier layers 780 may still function as a lithium barrier layer and, in some embodiments, as a coupling layer for waveguide 710.

Thus, TFLC PICs 700 and 700′ may share the benefits of electro-optic device 600, 600′, 100′″, 200, and 300″ as well as electro-optic devices 100, 100′, 100″, 300, and 300′. The use of barrier layers 770 and 780 may not only reduce lithium contamination but also improve optical coupling with other devices.

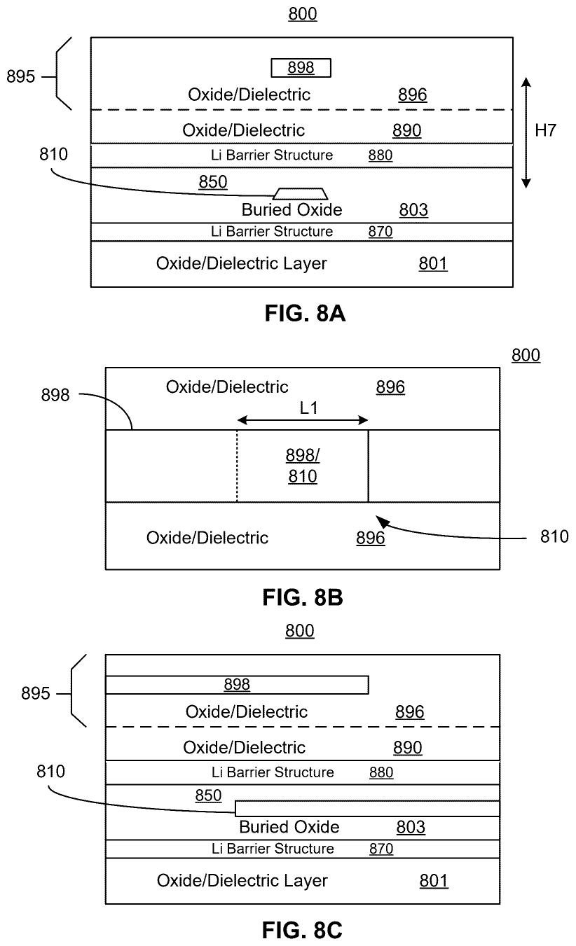

FIGS. 8A-8C depict an embodiment TFLC PICs 800 that utilize barrier structures. FIG. 8A depicts a cross-sectional view of TFLC PIC 800. FIG. 8B depicts a plan view of TFLC PIC 800. FIG. 8C depicts a cross-sectional side view of TFLC PIC 800. TFLC PIC 800 is analogous to TFLC PICs 600 and 700. TFLC photonics PIC 800 include dielectric layers 801 and 803, waveguide 810, electrodes 820 and 830, cladding 850, and dielectric 890 as well as lithium barrier structures 870 and 880 that are analogous to dielectric layers 601 and 603, waveguide 610, electrodes 620 and 630, cladding 650, and dielectric 690 as well as lithium barrier structures 670 and 680, respectively. Thus, the structure and function of dielectric layers 801 and 803, waveguide 810, electrodes 820 and 830, cladding 850, and dielectric 890 as well as lithium barrier structures 870 and 880 that are analogous to corresponding portions of TFLC PICs 600 and 600′. Although not shown, TFLC PIC 800 may include barrier layers that are analogous to barrier layers 672 and 674. Although barrier layer 880 is configured in an analogous manner to barrier layer 680 (e.g., is substantially flat), in some embodiments, barrier layer 880 may have a topology analogous to barrier layer 780.

Barrier layer 880 may be explicitly configured to facilitate optical coupling with another device. Thus, device 895 including dielectric 896 and waveguide 898 is also shown. The bond line between TFLC PIC 800 and device 895 is indicated by the dashed line in FIGS. 8A and 8C. As indicated in FIGS. 8B and 8C, waveguide 810 overlaps with waveguide 898 for a coupling length, L1. In addition, waveguide 810 is vertically separated from waveguide 898 by distance H7. In some embodiments, H7 is greater than one micrometer. In some embodiments, coupling length L1 is less than two hundred micrometers or less than three hundred micrometers. Barrier layer 880 may have a higher index of refraction that is closer to that of waveguide 810 and/or waveguide 880. For example, in some embodiments, barrier layer 880 (or the portion of barrier layer 880 in the coupling region at or around L1) may include or consist of SiN. Because of the configuration of barrier layer 880, a 0.1 dB (or less) coupling loss for the coupling length L1 and/or separation H7 may be achieved. In other embodiments, the coupling length (L1) and/or the distance between the waveguides (H7) may differ. The waveguide shapes and dimensions may be different than illustrated. For example, the waveguide(s) may be tapered.

Thus, TFLC PIC 800 and 800′ may share the benefits of electro-optic device 600, 600′, 700, 700′ 100′″, 200, and 300″ as well as electro-optic devices 100, 100′, 100″, 300, and 300′. The use of barrier layers 870 and 880 may not only reduce lithium contamination but also improve optical coupling with other devices.

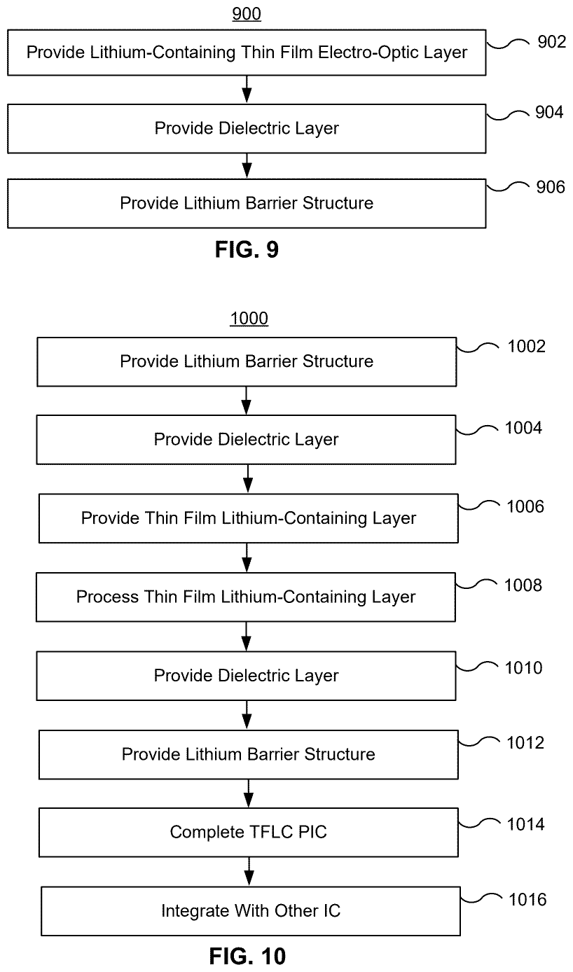

FIG. 9 is a flow chart depicting an embodiment of method 900 for providing an electro-optic device including a barrier structure. Method 900 is described in the context of processes that may have sub-processes. Although described in a particular order, another order not inconsistent with the description herein may be utilized.

A TFLC layer is provided, at 902. 902 may include depositing an LN and/or LT layer. In some embodiments, the layer is patterned. A dielectric layer is provided, a 904. A lithium barrier structure is provided, at 906. Providing the lithium barrier structure may include depositing at least one of a silicon nitride layer, a silicon oxynitride layer, a titanium nitride layer, aluminum oxide or a tantalum nitride layer of sufficient thickness to reduce or prevent lithium diffusion. In some embodiments, 906 includes depositing or growing multiple barrier layers. A barrier layer may be formed before formation of the TFLC layer at 902.

For example, referring to FIG. 6A, TFLC layer 610 is formed at 902. In some embodiments, 902 includes patterning the TFLC layer to form waveguide 610. Oxide layer(s) 603 or 650 are formed, at 904. Thus, 904 may occur before or after 902. In some embodiments, a portion of 904 occurs before 902 (e.g., formation of barrier layer 670) and a portion of 904 occurs after 902 (e.g., formation of cladding 650). Barrier layer 670 and/or 680 are formed at 906. Barrier layer 670 is formed prior to TFLC layer 610, while barrier layer 680 is formed after TFLC layer 610. In some embodiments, barrier layers 672 and 674 may also be formed. Using method 900, a device having improved performance may be formed. In particular, lithium diffusion may be reduced or eliminated and coupling to other devices may be improved.

FIG. 10 is a flow chart depicting an embodiment of method 1000 for providing an electro-optic device including a barrier structure. Method 1000 is described in the context of processes that may have sub-processes. Although described in a particular order, another order not inconsistent with the description herein may be utilized.

A lithium barrier structure is provided, at 1002. 1010 may include depositing at least one of a silicon nitride layer, a silicon oxynitride layer, a titanium nitride layer, an aluminum oxide layer or a tantalum nitride layer of sufficient thickness to reduce or prevent lithium diffusion. In some embodiments, 1002 includes depositing or growing multiple barrier layers. A dielectric layer is provided on the lithium barrier structures, at 1004. A TFLC layer is provided, at 1006. In some embodiments, 1006 may include depositing an LN and/or LT layer. At 1008, the TFLC layer is patterned. Thus, waveguides and/or other structures may be formed. A dielectric layer is provided, a 1010. A lithium barrier structure is provided, at 1012. Providing the lithium barrier structure at 1010 may include depositing at least one of a silicon nitride layer, a silicon oxynitride layer, a titanium nitride layer, aluminum oxide or a tantalum nitride layer of sufficient thickness to reduce or prevent lithium diffusion. In some embodiments, 1010 includes depositing or growing multiple barrier layers. In addition, 1010 may include performing a CMP or other planarization step prior to formation of the barrier layer. Processing of the TFLC PIC may be completed at 1014. The TFLC PIC formed may be integrated with another device, including but not limited to a silicon photonic and/or CMOS device, at 1016. For example, the TFLC PIC may be bonded with the other device.

For example, referring to FIGS. 8A-8C, barrier layer 870 is formed, at 1002. Oxide layer 803 is formed at 1004. TFLC layer 810 is formed at 1006. At 1008, the TFLC layer is patterned to form waveguide 810. Oxide layer 650 is formed, at 1010. Barrier layer 880 is formed at 1012. In addition, barrier layers (not shown in FIGS. 8A-8C) at the edges of TFLC PIC 800 may be formed. TFLC PIC 800 is completed, at 1014. TFLC PIC 800 is bonded with device 895, at 1016. Using method 1000, a device having improved performance may be formed. In particular, lithium diffusion may be reduced or eliminated and coupling to other devices may be facilitated.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A photonics device, comprising:
a thin film lithium-containing (TFLC) electro-optic layer;
a lithium barrier structure; and
an insulating layer between the TFLC electro-optic layer and the lithium barrier structure.

2. The photonics device of claim 1, further comprising:
an additional lithium barrier structure, the TFLC electro-optic layer being between the additional lithium barrier structure and the lithium barrier structure.

3. The photonics device of claim 2, further comprising:
an additional insulating layer between the TFLC electro-optic layer and the additional lithium barrier structure.

4. The photonics device of claim 2, TFLC electro-optic layer includes at least one waveguide having a waveguide width and wherein the lithium barrier structure has a width of at least twenty-five multiplied by the waveguide width.

5. The photonics device of claim 4, wherein the lithium barrier structure extends across the photonics device.

6. The photonics device of claim 2, wherein the lithium barrier structure has at least one of a low permeability material or a low diffusivity constant material.

7. The photonics device of claim 2, wherein the lithium barrier structure includes at least one of a silicon nitride layer, a silicon oxynitride layer, an aluminum oxide layer, a titanium nitride layer, or a tantalum nitride layer.

8. The photonics device of claim 2, wherein the is TFLC electro-optic layer includes at least one waveguide, the lithium barrier structure being between the at least one waveguide and at least one additional waveguide of an additional device, the barrier structure being configured to facilitate coupling between the at least one additional waveguide and the at least one waveguide such that a coupling loss between the at least one waveguide and the at least one additional waveguide is not more than 0.1 dB for a constrained coupling length of less than 200 micrometers.

9. The photonics device of claim 8, wherein the at least one waveguide is separated from the at least one additional waveguide by greater than one micrometer.

10. The photonics device of claim 8, wherein the additional lithium barrier structure is between the waveguide and a substrate.

11. An integrated photonics device, comprising:
a thin film lithium-containing (TFLC) photonics integrated circuit (TFLC PIC) including a waveguide, a first lithium barrier structure, a second lithium barrier structure, a first dielectric layer, a second dielectric layer, and a plurality of electrodes in proximity to a portion of the waveguide, the waveguide including a TFLC electro-optic material being between the first dielectric layer and the second dielectric layer, the first dielectric layer being between the first lithium barrier structure and the waveguide, the second dielectric layer being between the second lithium barrier structure and the waveguide, the first dielectric layer and the second dielectric layer encapsulating the waveguide, the first lithium barrier structure and the second lithium barrier structure each having a width of at least twenty-five multiplied by a waveguide width; and
an additional integrated circuit including an additional waveguide, the second lithium barrier structure being between the additional waveguide and the waveguide.

12. The integrated photonics device of claim 11, wherein the first lithium barrier structure and the second lithium barrier structure each extends across the TFLC PIC.

13. The integrated photonics device of claim 12 wherein at least one of the first lithium barrier structure or the second lithium barrier structure has at least one of a low permeability material or a low diffusivity constant material.

14. The integrated photonics device of claim 12, wherein the lithium barrier structure includes at least one of a silicon nitride layer, a silicon oxynitride layer, an aluminum oxide layer, a titanium nitride layer, or a tantalum nitride layer.

15. The integrated photonics device of claim 12, wherein the second barrier structure is configured to facilitate coupling between the additional waveguide and the waveguide such that a coupling loss between the waveguide and the additional waveguide is not more than 0.1 dB for a constrained coupling length of less than 200 micrometers and a separation between the waveguide and the additional waveguide of greater than one micrometer.

16. A method, comprising:
providing a first lithium barrier structure;
providing a first insulating layer on the first barrier structure;
providing a thin film lithium-containing (TFLC) electro-optic layer on the first insulating layer, the first insulating layer being between the TFLC electro-optic layer and the first lithium barrier structure;
providing a second insulating layer on the TFLC electro-optic layer; and
providing a second lithium barrier structure on the second insulating layer, the second insulating layer being between the TFLC electro-optic layer and the second insulating barrier structure.

17. The method of claim 16, further comprising:
forming at least one waveguide from the TFLC electro-optic layer, the at least one waveguide having a waveguide width, the first lithium barrier structure and the second lithium barrier structure each having a width of at least twenty-five multiplied by the waveguide width.

18. The method of claim 17, wherein each of the first lithium barrier structure and the second lithium barrier structure includes at least one of a silicon nitride layer, a silicon oxynitride layer, an aluminum oxide layer, a titanium nitride layer, or a tantalum nitride layer.

19. The method of claim 17, wherein the second lithium barrier structure is between the waveguide and an additional waveguide of an additional device, the second lithium barrier structure being configured to facilitate coupling between the additional waveguide and the waveguide such that a coupling loss between the waveguide and the additional device is not more than 0.1 dB for a constrained coupling length of less than 200 micrometers.

20. The method of claim 19, wherein the waveguide is separated from the additional waveguide by greater than one micrometer.
